(19) United States
(12) Patent Application Publication
(10) Pub. No.: US 2025/0079397 A1
(43) Pub. Date: Mar. 6, 2025

(54) BONDING METHOD, BONDING APPARATUS AND ARTICLE MANUFACTURING METHOD

(71) Applicant: CANON KABUSHIKI KAISHA, Tokyo (JP)

(72) Inventors: SHUN TOKAIRIN, Tochigi (JP); TERUHISA NAWAMAKI, Tochigi (JP)

(21) Appl. No.: 18/781,169

(22) Filed: Jul. 23, 2024

(30) Foreign Application Priority Data
Aug. 30, 2023 (JP) 2023-140268

(51) Int. Cl. H01L 23/00; H01L 21/66; H01L 21/68; H01L 25/00

(52) U.S. Cl. CPC H01L 24/95; H01L 21/681; H01L 22/20; H01L 24/74; H01L 25/50; H01L 2224/95121; H01L 2224/95136

(57) ABSTRACT

A bonding method of bonding a third object after bonding a second object to a first object, the method including evaluating a bonding result of bonding the second object to the first object, deciding, based on the bonding result, the third object to be bonded to the first object bonded with the second object from a plurality of the third objects, and bonding, based on the decision in the deciding, the third object to the first object bonded with the second object.

### BACKGROUND OF THE INVENTION

### Field of the Invention

The present invention relates to a bonding method, a bonding apparatus and an article manufacturing method.

### Description of the Related Art

Japanese Patent Laid-Open No. 2000-68296 proposes a technique of, when bonding the first object and the second object in a bonding apparatus, bonding non-defective objects together and bonding defective objects together based on the quality information concerning the first object and the second object obtained in advance. According to the technique disclosed in Japanese Patent Laid-Open No. 2000-68296, the yield of an article (device or the like) manufactured by bonding the first object and the second object can be improved.

However, in a case of performing bonding a plurality of times such as a case of bonding the third object to the first object bonded with the second object, depending on the bonding state (bonding result) between the first object and the second object, the consistency with the quality information of the first object obtained in advance may be lost. For example, in a case where the positional shift between the first object and the second object bonded to the first object exceeds the allowable range, even if the first object itself is a non-defective object, the first object (the bonded object obtained by bonding the second object to the first object) should be treated as a defective object when bonding the third object thereto. In this manner, the conventional technique does not consider the influence of bonding of the first object and the second object on the quality information obtained in advance, so the sufficient effect of improving the yield is not always obtained.

### SUMMARY OF THE INVENTION

The present invention provides a technique advantageous in improving the yield of a bonded object including the first object, the second object, and the third object and obtained by performing bonding a plurality of times.

According to one aspect of the present invention, there is provided a bonding method of bonding a third object after bonding a second object to a first object, the method including evaluating a bonding result of bonding the second object to the first object, deciding, based on the bonding result, the third object to be bonded to the first object bonded with the second object from a plurality of the third objects, and bonding, based on the decision in the deciding, the third object to the first object bonded with the second object.

Further aspects of the present invention will become apparent from the following description of exemplary embodiments with reference to the attached drawings.

### BRIEF DESCRIPTION OF THE DRAWINGS

FIG. 1 is a view schematically showing the arrangement of a bonding apparatus as one aspect of the present invention.

FIG. 2 is a top view showing a wafer stage viewed from the +Z direction.

FIG. 3 is a flowchart for explaining a bonding operation in the bonding apparatus shown in FIG. 1.

FIG. 4 is a view showing an example of rank information.

FIG. 5 is a top view showing a wafer viewed from the +Z direction.

FIG. 6 is a view showing the configuration of a bonding system.

FIG. 7 is a flowchart for explaining a bonding operation in the bonding system shown in FIG. 6.

FIG. 8 is a flowchart for specifically explaining a process in the first bonding apparatus shown in FIG. 7.

FIG. 9 is a flowchart for specifically explaining a process in the second bonding apparatus shown in FIG. 7.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

In the following description, a substrate is a wafer on which a plurality of first dies (first objects) each including a semiconductor device have been formed. Further, a carrier is a dicing frame mounted with a plurality of second dies (second objects) and a plurality of third dies (third objects) separated into pieces, on each of which a semiconductor device has been formed. However, the carrier and substrate are not limited to this. The second die and the third die may be dies of the same kind or different kinds.

The first object includes, in addition to the die of the semiconductor device formed on the wafer, for example, a silicon interposer as a silicon wafer with wirings formed thereon, and a glass interposer as a glass wafer with wirings formed thereon. The first object also includes an organic interposer as an organic panel (PCB) with wirings formed thereon, a wafer formed with a semiconductor device, to which some dies including semiconductor devices have already been bonded, and the like.

Each of the second object and the third object includes, in addition to the separated die, for example, a stack of some already separated dies, a small piece of a material, an optical element, a MEMS, a structure, or the like. The bonding method of the first object, the second object, and the third object is also not limited. The bonding method of the first object, the second object, and the third object includes, for example, bonding using an adhesive agent, temporary bonding using a temporary adhesive agent, bonding by hybrid bonding, atomic diffusion bonding, vacuum bonding, bump bonding, and the like. In this manner, the bonding method of the first object, the second object, and the third object includes various temporary bonding methods and permanent bonding methods.

Industrial application examples of the bonding apparatus as one aspect of the present invention are, for example, application examples described below.

The first application example is manufacturing of a stacked memory. When the bonding apparatus as one aspect of the present invention is applied to manufacturing of a stacked memory, the first object is a memory die as a semiconductor device formed on a wafer, and the second object and the third object are separated memory dies. In manufacturing of a stacked memory, in general, about eight layers are stacked. Hence, in bonding of the seventh layer, the first object is the substrate as the wafer with six layers of memory dies already bonded thereon. In bonding of the eighth layer, the first object is the substrate with the memory die (second object) bonded thereon as the seventh layer. Note that the final layer may be a driver die for driving the memories.

The second application example is heterogeneous integration of a processor. The mainstream of a conventional processor is an SoC obtained by forming a logic circuit and an SRAM in one semiconductor element. To the contrary, in heterogeneous integration, respective elements are manufactured on separate wafers while applying a process optimal for each element, and bonded to manufacture a processor. When the bonding apparatus as one aspect of the present invention is applied to heterogeneous integration, the first object is a logic die as a semiconductor device formed on the wafer. Each of the second object and the third object is a die such as an SRAM, an antenna, or a driver separated after probing. Normally, different dies are sequentially bonded. Hence, the bonded objects on the first object sequentially increase. For example, in a case of starting bonding from an SRAM, the logic die without bonding serves as the first object, and the SRAM serves as the second object. When bonding the die (third die) next to the SRAM, the logic wafer with the SRAM bonded thereto serves as the first object.

The third application example is 2.5D bonding using a silicon interposer. The silicon interposer is a silicon wafer with wirings formed thereon. The 2.5D bonding is a method of bonding separated dies using the silicon interposer, thereby electrically bonding the dies. When the bonding apparatus as one aspect of the present invention is applied to die bonding to the silicon interposer, the first object is a silicon interposer as a silicon wafer with wirings formed thereon, and each of the second object and the third object is a separated die. In general, a plurality of kinds of dies are bonded to the silicon interposer. Hence, the first object also includes a silicon interposer with several dies bonded thereto.

The fourth application example is 2.1D bonding using an organic interposer or a glass interposer. The organic interposer is an organic panel (PCB substrate or CCL substrate) used as a package substrate, on which wirings are formed. The glass interposer is a glass panel with wirings formed thereon. The 2.1D bonding is a method of bonding separated dies to the organic interposer or the glass interposer, thereby electrically bonding the dies by the wirings on the interposer. When the bonding apparatus as one aspect of the present invention is applied to die bonding to the organic interposer, the first object is an organic panel formed with wirings, and each of the second object and the third object is a separated die. When the bonding apparatus as one aspect of the present invention is applied to die bonding to the glass interposer, the first object is a glass panel formed with wirings, and each of the second object and the third object is a separated die. In general, a plurality of kinds of dies are bonded to the organic interposer or the glass interposer. Hence, the first object also includes an organic interposer or a glass interposer with several dies bonded thereto.

The fifth application example is heterogeneous substrate bonding. For example, in the field of infrared image sensors, InGaAs is known as a high sensitivity material. Accordingly, if InGaAs is used for a sensor unit that receives light, and silicon capable of implementing high-speed processing is used for a logic circuit that extracts data, a high-sensitivity high-speed infrared image sensor can be manufactured. However, from InGaAs crystal, only substrates (wafers) whose diameter is as small as 4 inches are mass-produced, which is smaller than a mainstream silicon wafer having a size of 300 mm. Hence, a technique of bonding a separated InGaAs substrate to a 300-mm silicon wafer with a logic circuit formed thereon has been proposed. The bonding apparatus as one aspect of the present invention can also be applied to heterogeneous substrate bonding for bonding substrates made of different materials and having different sizes. When the bonding apparatus as one aspect of the present invention is applied to heterogeneous substrate bonding, the first object is a substrate such as a silicon wafer with a large diameter, and each of the second object and the third object is a small piece of a material such as InGaAs. Note that the small piece of the material is a slice of a crystal. The piece is preferably cut into a rectangular shape.

### First Embodiment

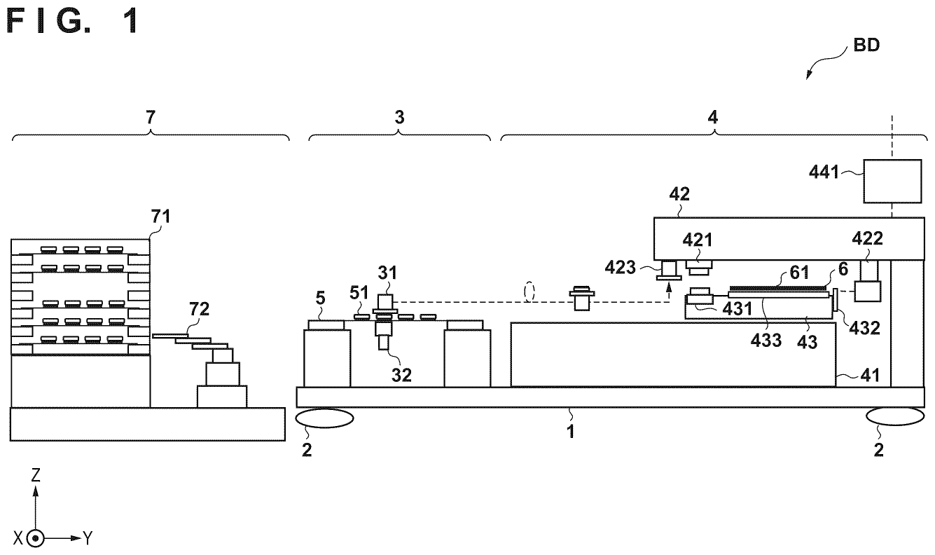

FIG. 1 is a view schematically showing the arrangement of a bonding apparatus BD as one aspect of the present invention. The bonding apparatus BD bonds separated dies 51 (second object and third object) to a die 61 (first object) at an arbitrary position on a wafer 6 serving as a substrate. In this embodiment, the bonding apparatus BD conveys the wafer 6 with a plurality of dies 61 formed thereon, and a dicing frame 5 mounted with a plurality of dies 51, and sequentially bonds two dies 51 (second die and third die) to the die 61 (first die). The dies 51 are provided while being arrayed (held) on a dicing tape put on the dicing frame 5 (first carrier and second carrier). In this specification, as shown in respective drawings, directions are indicated on an XYZ coordinate system. Typically, an XY plane is a plane parallel to the horizontal plane, and a Z-axis is an axis parallel to the vertical direction. X-, Y-, and Z-axes are examples of directions that are orthogonal to each other or cross each other.

As shown in FIG. 1, the bonding apparatus BD includes a pickup unit 3 and a bonding unit 4, which are arranged on a base 1 damped by mounts 2, and a frame supply unit 7. The pickup unit 3 and the bonding unit 4 function as a bonding unit for bonding the dies 51 (second object and third object) to the die 61 (first object) on the wafer 6 under the control of a control unit 441 (to be described later). In this embodiment, the pickup unit 3 and the bonding unit 4 are arranged on one base 1. However, the pickup unit 3 and the bonding unit 4 may individually be arranged on separate bases.

The frame supply unit 7 includes a frame magazine 71 and a frame conveyance arm 72. The frame magazine 71 is formed to be detachable, and supplied from outside the apparatus while storing (mounted with) a plurality of dicing frames 5. The frame conveyance arm 72 takes out the dicing frame 5 from the frame magazine 71, and conveys (passes) the dicing frame 5 to the pickup unit 3. Further, the frame conveyance arm 72 conveys (returns) the dicing frame 5 completed with a bonding process from the pickup unit 3 to the frame magazine 71. Note that, in this embodiment, only one frame conveyance arm 72 conveys the dicing frame 5, but a plurality of frame conveyance arms 72 may relay the dicing frame 5. Furthermore, from the viewpoint of shortening the exchange time of the frame magazine 71 and the conveyance time of the dicing frame 5, the bonding apparatus BD may include a plurality of frame supply units 7.

The frame supply unit 7 may be arranged at a position away from a wafer supply unit that supplies the wafer 6 to the bonding unit 4 (conveys the wafer 6 to/from the bonding unit 4). Alternatively, the frame supply unit 7 may be arranged adjacent to the wafer supply unit and partially share a conveyance arm and a conveyance path including them.

The pickup unit 3 includes a pickup head 31 and a release head 32. The pickup unit 3 peels the die 51 to be bonded to the wafer 6 from the dicing tape by the release head 32, and holds the die 51 peeled from the dicing tape by sucking (chucking) it with the pickup head 31. The pickup head 31 rotates the die 51 by, for example, 180° and passes it to a bonding head 423 of the bonding unit 4.

The bonding unit 4 includes a stage base 41 and an upper base 42. A wafer stage 43 is mounted on the stage base 41. The wafer stage 43 is configured to be capable of driving concerning the X direction and the Y direction by a driving mechanism (not shown) such as a linear motor. The wafer stage 43 may be configured to be capable of driving concerning a rotation about an axis parallel to the Z direction. Instead of driving the wafer stage 43 concerning the rotation about the axis parallel to the Z direction, the bonding head 423 may drive the die 51 concerning the rotation about the axis parallel to the Z direction.

A die observation camera 431 is provided on the wafer stage 43. The die observation camera 431 obtains an image by capturing the die 51 held by the bonding head 423. From the image obtained by the die observation camera 431, the control unit 441 obtains the position of the feature point of the die 51 (second object or third object) held by the bonding head 423, the outer diameter dimension of the die 51, and the height-direction (Z-direction) distances of a plurality of points of the measurement surface of the die 51 (the flatness of the die 51). In this manner, the die observation camera 431 cooperates with the control unit 441, thereby implementing a function of measuring the position of the feature point (portion) of the die 51, the outer diameter dimension of the die 51, and the flatness of the die 51.

A bar mirror 432 is provided on the wafer stage 43. The bar mirror 432 is used as the target of an interferometer 422. The wafer stage 43 holds the wafer 6 via a wafer chuck 433.

A wafer observation camera 421 is provided on the upper base 42. The wafer observation camera 421 obtains an image by capturing the wafer 6 held by the wafer stage 43 (wafer chuck 433). From the image obtained by the wafer observation camera 421, the control unit 441 obtains the position of the feature point of the die 61 (first object) on the wafer 6 held by the wafer stage 43, and the height-direction (Z-direction) distances of a plurality of points of the measurement surface of the wafer 6 (the flatness of the wafer 6). In this manner, the wafer observation camera 421 cooperates with the control unit 441, thereby implementing a function of measuring the position of the feature point (portion) of the die 61 on the wafer 6 and the flatness of the wafer 6. The wafer observation camera 421 may be a camera capable of measuring an element pattern or mark formed on the wafer or inside the wafer by using infrared light as measurement light.

The upper base 42 is further provided with the interferometer 422 for measuring the position of the wafer stage 43 using the bar mirror 432, and the bonding head 423 for holding the die 51 passed from the pickup head 31.

When bonding the die 51 to the wafer 6 (die 61 thereon), for example, the bonding head 423 is driven downward (−Z direction) to bond the die 51 held by the bonding head 423 to the wafer 6 held by the wafer stage 43. Alternatively, the wafer stage 43 or the wafer chuck 433 may be driven upward (+Z direction) to bond the die 51 held by the bonding head 423 to the wafer 6 held by the wafer stage 43.

In this embodiment, the configuration is employed in which the pickup head 31 rotates the die 51 by 180° and passes it to the bonding head 423. However, by providing one or more die holding units between the pickup head 31 and the bonding head 423, the pickup head 31 may pass the die 51 to the die holding unit, and the die holding unit may pass the die 51 to the bonding head 423. Alternatively, a driving mechanism that drives the bonding head 423 may be provided and drive the bonding head 423 such that the bonding head 423 receives the die 51 from the pickup head 31. Note that, in order to improve productivity, the bonding apparatus BD may include a plurality of pickup heads, a plurality of release heads, and a plurality of bonding heads.

The bonding apparatus BD further includes the control unit 441 formed by an information processing apparatus (computer) including a CPU, a memory, and the like. The control unit 441 operates the bonding apparatus BD by comprehensively controlling the respective units of the bonding apparatus BD, for example, the pickup unit 3, the bonding unit 4, and the like in accordance with a program stored in a memory unit. As will be described later, the control unit 441 functions as an evaluation unit that evaluates the bonding result of bonding the die 51 (second object) to the die 61 (first object). In this embodiment, the control unit 441 also functions as a decision unit that decides, based on the bonding result of the die 61 (first object) and the die 51 (second object), a combination of the die 61 bonded with the die 51 and the die 51 (third object) to be bonded to the die 61. In this manner, the control unit 441 decided, from the plurality of dies 51 (third objects), the die 51 (third object) to be bonded to the die 61 (first object) bonded with the die 51 (second object).

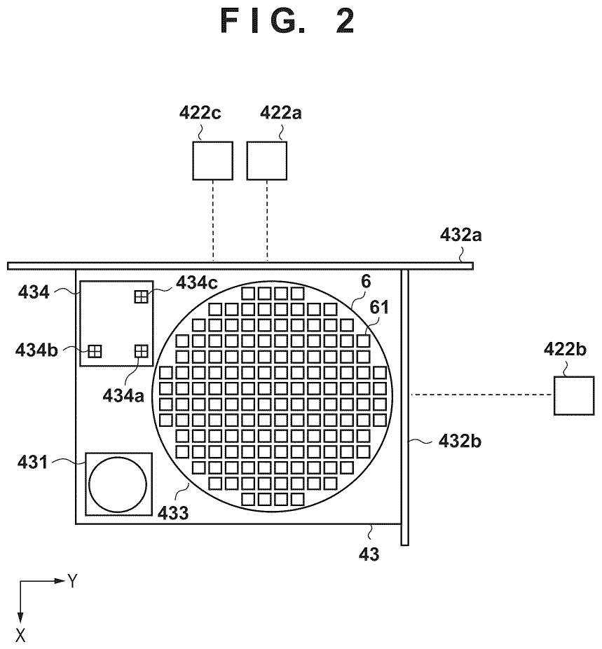

FIG. 2 is a top view showing the wafer stage 43 from the +Z direction. The wafer 6 is held by the wafer stage 43 via the wafer chuck 433. The wafer 6 or the wafer stage 43 is positioned concerning the X direction and the Y direction, which are orthogonal to each other or cross each other, and the rotation about the axis parallel to the Z direction orthogonal to the X and Y directions. For this purpose, the wafer stage 43 is provided with the bar mirror 432, more specifically, a bar mirror 432a and a bar mirror 432b. The bar mirror 432a is used as the target of interferometers 422a and 422c. The control unit 441 can obtain the position of the wafer stage 43 in the X direction based on the output from the interferometer 422a, and obtain the rotation (rotation amount) of the wafer stage 43 about the axis parallel to the Z direction based on the outputs from the interferometers 422a and 422c (difference thereof). The bar mirror 432b is used as the target of an interferometer 422b. The control unit 441 can obtain the position of the wafer stage 43 in the Y direction based on the output from the interferometer 422b. Based on the outputs from the interferometers 422a, 422b, and 422c, the control unit 441 feedback-controls the wafer 6 or the wafer stage 43 concerning the X direction, the Y direction, and the rotation about the axis parallel to the Z direction orthogonal to the X and Y directions. In this manner, the interferometer 422 and the control unit 441 function as a positioning mechanism that two-dimensionally accurately positions the wafer 6 or the wafer stage 43.

A reference plate 434 is provided on the wafer stage 43 (upper surface thereof). In this embodiment, a plurality of marks 434a, 434b, and 434c are arranged (drawn) on the reference plate 434. The reference plate 434 is made of a material with a low thermal expansion coefficient, and the marks 434a, 434b, and 434c are drawn at a high position accuracy. For example, the reference plate 434 is formed by a quartz substrate, and the marks 434a, 434b, and 434c are drawn thereon using the drawing method of a semiconductor lithography process. The reference plate 434 has a surface with substantially the same height as the surface of the wafer 6, and can be observed by the wafer observation camera 421. A camera used to observe the reference plate 434 may separately be provided.

The wafer stage 43 may have a configuration that combines a coarse motion stage that is driven within a large range, and a fine motion stage that is accurately driven within a small range. In this configuration, the die observation camera 431, the bar mirrors 432a and 432b, the wafer chuck 433, and the reference plate 434 are provided on the fine motion stage to implement accurate positioning.

A method of guaranteeing the origin position, the magnification, and the directions (rotations) and orthogonality of the X-axis and the Y-axis of the wafer stage 43 using the reference plate 434 will be described here. The mark 434a is observed by the wafer observation camera 421, and the measured value (output value) of the interferometer when the mark 434a is located at the center of the image obtained by the wafer observation camera 421 is defined as the origin of the wafer stage 43. Next, the mark 434b is observed by the wafer observation camera 421, and the direction (rotation) of the Y-axis of the wafer stage 43 and the magnification in the Y direction are decided based on the measured value of the interferometer when the mark 434b is located at the center of the image obtained by the wafer observation camera 421. Next, the mark 434c is observed by the wafer observation camera 421, and the direction (rotation) of the X-axis of the wafer stage 43 and the magnification in the X direction are decided based on the measured value of the interferometer when the mark 434c is located at the center of the image obtained by the wafer observation camera 421.

In this manner, defining the direction from the mark 434b of the reference plate 434 to the mark 434a as the Y-axis of the bonding apparatus BD, and the direction from the mark 434c to the mark 434a as the X-axis of the bonding apparatus BD, the directions and orthogonality of the axes can be calibrated. Also, defining the interval between the mark 434b and the mark 434a as the scale reference of the Y-axis of the bonding apparatus BD and the interval between the mark 434c and the mark 434a as the scale reference of the X-axis of the bonding apparatus BD, calibration can be performed.

In the interferometer, the refractive index of the optical path changes due to variations of the atmospheric pressure and temperature, and this makes the measured value vary. Therefore, it is preferable to perform calibration at an arbitrary timing and guarantee the origin position, the magnification, and the directions (rotations) and orthogonality of the X-axis and the Y-axis of the wafer stage 43. To reduce the variation of the measured value of the interferometer, the space in which the wafer stage 43 is arranged may be covered with a temperature control chamber to control the temperature in the temperature control chamber.

In this embodiment, a case where the reference plate 434 provided on the wafer stage 43 is observed by the wafer observation camera 421 has been described, but the present invention is not limited thereto. For example, by providing the reference plate 434 on the upper base 42, and observing the reference plate 434 provided on the upper base 42 by the die observation camera 431, the origin position, the magnification, the directions (rotations) and orthogonality of the X-axis and the Y-axis of the wafer stage 43 may be guaranteed. Instead of performing calibration by observing the reference plate 434, for example, calibration may be performed by an abutting operation to a reference surface, or accurate positioning may be performed using a position measurement device such as a white interferometer that guarantees an absolute value.

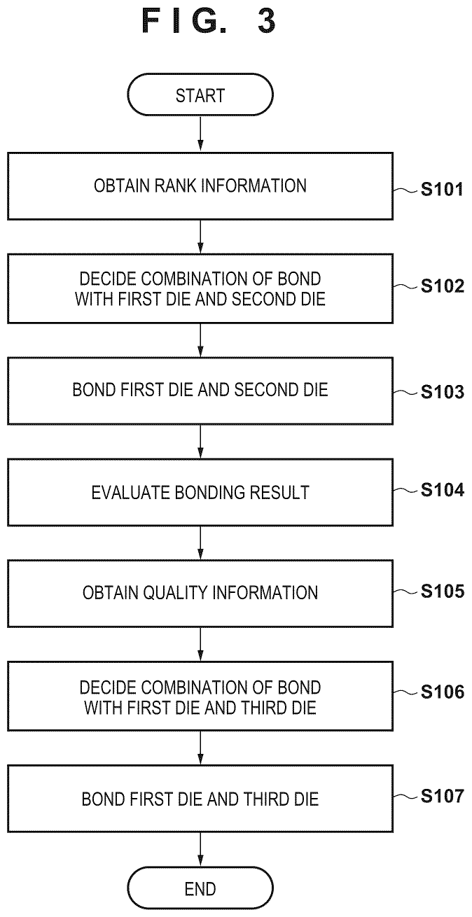

With reference to FIG. 3, an operation in the bonding apparatus BD, that is, a bonding operation (bonding method) of bonding the die 51 (second object) to the die 61 (first object) on the wafer 6, and further bonding the die 51 (third object) to the die 61 bonded with the die 51 will be described. Here, assume that a step of conveying, to the bonding apparatus BD, the wafer 6 formed with the die 61 (first object), and the dicing frame 5 (first carrier or second carrier) mounted with the plurality of dies 51 (second objects and third objects) is performed.

In this embodiment, a combination of the die 51 and the die 61 to be bonded to the die 51 is decided such that the die 51 and the die 61 are bonded in descending order of the priority order of the combination of the rank of the die 51 and the rank of the die 61. Then, the die 51 and the die 61 are bonded in accordance with the decided combination. Note that the priority order is set (decided in advance) such that the combination in which the rank of the die 51 and the rank of the die 61 are more similar has a higher priority order. For example, the priority order is set such that the combination in which the rank of the die 51 and the rank of the die 61 are the same has the highest priority order. More specifically, in a case where the rank of the die 51 and the rank of the die 61 are expressed by “non-defective” or “defective”, the priority order is set such that the highest priority is given to the combination in which both the die 51 and the die 61 are non-defective dies and the combination in which both the die 51 and the die 61 are defective dies. The die 51 is bonded to the defective die 61 because it is necessary to bond (arrange) the die 51 even to the defective die 61 to suppress a deterioration in uniformity in the molding and bonding processes. Here, if one of the die 51 and the die 61 is a defective die, the bonded object (device) obtained by bonding the die 51 to the die 61 is a defective object. In this manner, if a non-defective die and a defective die are bonded, the non-defective die is wasted and the yield decreases. Therefore, in order not to waste a non-defective die, the priority order is preferably set such that the defective die 51 is bonded to the defective die 61.

Further, even if the non-defective die 61 (first object) and the non-defective die 51 (second object) are bonded, depending on the positional shift upon bonding them, the die 61 bonded with the die 51 (after bonding) may become a defective die. Accordingly, if the die 51 (third object) is further bonded to the die 61 (first object) without considering the quality deterioration of the die 61 (first object) after bonding, the non-defective die 51 (third object) may be bonded to the defective die 61 (first object) after bonding.

To solve this problem, in this embodiment, the bonding result of bonding the die 51 (second object) to the die 61 (first object) is evaluated, and based on the evaluation result, a combination of the die 61 bonded with the die 51 and the die 51 (third object) to be bonded to the die 61 is decided. Note that, in the following description, the die 61 formed on the wafer 6 may be referred to as the first die, and the dies 51 to be sequentially bonded to the die 61 may be referred to as the second die and the third die. Further, in this embodiment, the second die and the third die are dies of the same kind, and the second die and the third die are mounted on the same dicing frame 5 (same carrier).

In step S101, rank information of the plurality of dicing frames 5 stored in the frame magazine 71 and to be supplied (conveyed) to the bonding apparatus BD, and the wafer 6 is obtained. In the manufacture of a semiconductor, after a semiconductor device is manufactured on a wafer, for example, a prober determines whether the device is a non-defective device or a defective device. In some cases, the device is classified (classified into multiple ranks) not only based on whether it is a non-defective device or a defective device, but also based on the performance (characteristic) such as speed. In this manner, the rank information is the data indicating the rank which is the classification determined from the class including the quality (data concerning the quality) of each of the dies 51 (second die and third die) and the die 61 (first die). Hence, in this embodiment, the rank information is obtained, which includes data indicating the rank of each of the dies 51 (second dies and third dies) mounted on the plurality of dicing frames 5, and data indicating the rank of each die 61 (first die) formed on the wafer 6. As has been described above, the rank information is obtained from an external apparatus such as the prober different from the bonding apparatus BD before starting supply of the dicing frame 5 and the wafer 6.

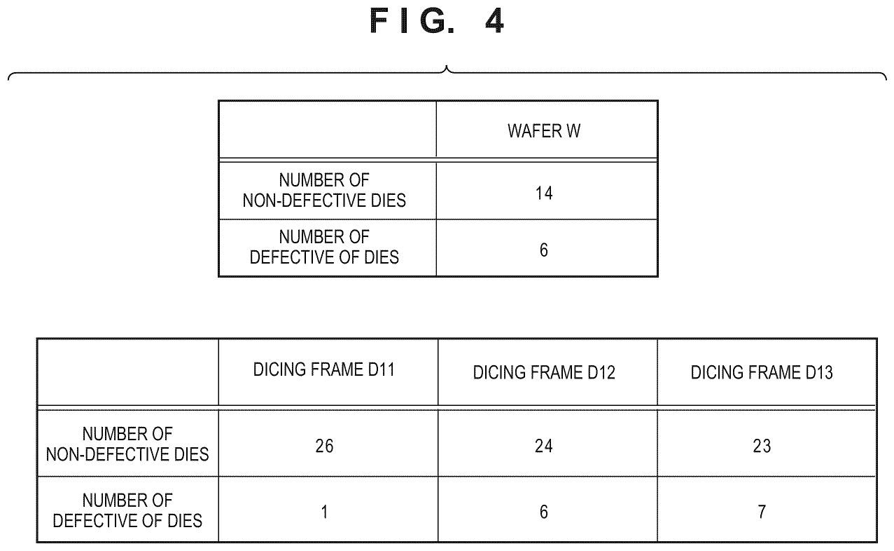

A case where three dicing frames D11, D12 and D13 and one wafer W are supplied to the bonding apparatus BD will be described below as an example. In this case, the rank information obtained in step S101 includes data indicating the number of non-defective/defective dies 61 (the number of non-defective dies and the number of defective dies) formed on the wafer W, as shown in FIG. 4. The rank information obtained in step S101 also includes data indicating the number of non-defective/defective dies 51 (second dies and third dies) (the number of non-defective dies and the number of defective dies) mounted on each of the dicing frames D11, D12, and D13, as shown in FIG. 4. Note that the number of the dies 61 formed on the wafer W is basically larger than the number of the dies 51 mounted on each of the dicing frames D11, D12, and D13.

In step S102, based on the rank information obtained in step S101, a combination of the first die (die 61) and the second die (die 51) to be bonded to the first die is decided such that non-defective dies are bonded together and defective dies are bonded together. If a combination of non-defective dies or a combination of defective dies cannot be decided, a combination of the non-defective first die and the defective second die or a combination of the defective first die and the non-defective second die is decided.

In step S103, in accordance with the combination decided in step S102, the dicing frame D11, D12, or D13 is conveyed to the pickup unit 3, the wafer W is conveyed to the bonding unit 4, and the second die (die 51) is bonded to the first die (die 61). Note that the bonding order is arbitrary as long as the combination of the first die and the second die to be bonded thereto matches the combination decided in step S102. If, among the dies mounted on the dicing frame, all the second dies included in the combinations decided in step S102 have been bonded to the first dies, the dicing frame is exchanged. Then, in accordance with the combinations decided in step S102, the second dies are bonded to all the first dies formed on the wafer W.

If the rank information shown in FIG. 4 is obtained, for example, by using the dicing frames D12 and D13 for the wafer W, all the first dies and the second dies can be bonded in a combination of non-defective dies and a combination of defective dies. Note that, if there are a plurality of combinations of the dicing frames that maximize the number of bonds in the combination of non-defective dies and the number of bonds in the combination of defective dies, a combination of the first die and the second die may be decided for one of those combinations.

In this embodiment, the rank information has been described as two-level ranking data indicating the quality of the die (first die, second die, and third die). However, as has been described above, the number of ranking levels may be an arbitrary number of three or more, and the criterion may be an arbitrary criterion other than the quality.

Further, in this embodiment, the combination of the same rank such as the combination of non-defective dies and the combination of defective dies is prioritized, but it is not always necessary to prioritize the combination of the same rank. For example, within the range where the rank of the die 51 and the rank of the die 61 are similar (that is, bonding of the die 51 and the die 61 is allowed), a combination of arbitrary ranks may be prioritized. It is only required that the priority order of the combination of arbitrary ranks is uniquely decided.

In step S104, the bonding result of bonding the second die to the first die in step S103 (that is, the quality of the first die after the second die is bonded thereto) is evaluated. At this time, the bonding result of the first die and the second die is evaluated using not an inspection apparatus such as a prober but various kinds of measuring devices included in the bonding apparatus BD. In this embodiment, as the bonding result of the first die and the second die, the positional shift amount between the first die and the second die bonded to the first die is evaluated.

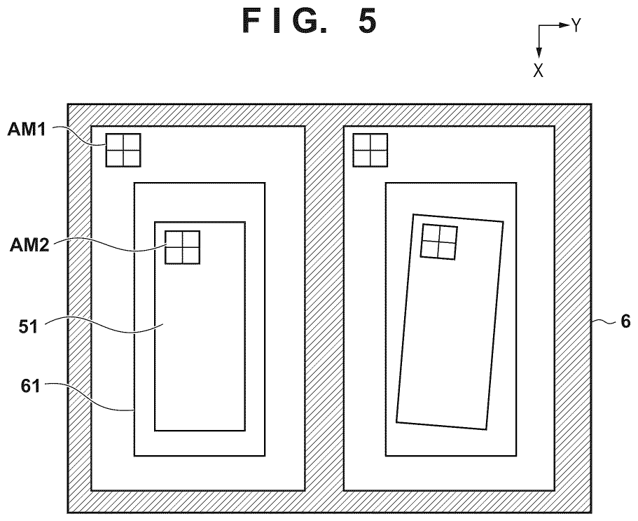

With reference to FIG. 5, a specific example of a method of evaluating the positional shift amount between the first die and the second die as the bonding result of the first die and the second die will be described. FIG. 5 is a top view showing the wafer 6 viewed from the +Z direction. For example, a first alignment mark AM1 for measurement is provided in the periphery of each die 61 (first die) on the wafer, and a second alignment mark AM2 for measurement is provided in each of the dies 51 (second die and third die) to be bonded to the die 61. After bonding the die 61 and the die 51, the die observation camera 431 captures the periphery of each die 51 to obtain a periphery image, and the relative distance between the first alignment mark AM1 and the second alignment mark AM2 in the periphery image is used as the positional shift amount between the die 61 and the die 51. The positional shift amount between the die 61 (first die) and the die 51 (second die) includes X, Y, and 0 (angle) components. Then, it is evaluated whether the positional shift amount between the first die and the second die falls within the allowable range (or outside the allowable range). Note that, from the relationship between the positional shift amount and the defective object rate based on the measurement results of electrical characteristic, the range of the positional shift amount that results in the defective object rate allowable as the yield is set as the allowable range. For example, letting X1, Y1, and 01 be allowable ranges, if conditions “X≤X1”, “Y≤Y1”, and “0≤01” are satisfied, the die 61 (first die) bonded with the die 51 (second die) is evaluated as a non-defective die. On the other hand, if “X>X1”, “Y>Y1”, or “θ>θ1”, the die 61 (first die) bonded with the die 51 (second die) is evaluated as a defective die. In this manner, if the positional shift amount between the first die and the second die falls within the allowable range, the first die bonded with the second die is evaluated as a non-defective die. If the positional shift amount between the first die and the second die falls outside the allowable range, the first die bonded with the second die is evaluated as a defective die. Note that the wiring formed in the die 51 (second die) may be stored as a template instead of the second alignment mark AM2, and the relative distance between the first alignment mark AM1 and the template of the die 51 may be used as the positional shift amount between the die 61 and the die 51.

In this embodiment, the case has been described in which the positional shift amount between the first die and the second die is obtained from the image (periphery image) obtained by capturing the first die bonded with the second die, but the present invention is not limited to this. For example, it is also possible to obtain (estimate) the positional shift amount between the first die and the second die from the load value (pressure value) upon bonding the second die to the first die. The load value upon bonding the second die to the first die can be obtained by, for example, a load sensor provided in the bonding head 423 or the wafer stage 43. It is also possible to obtain (estimate) the positional shift amount between the first die and the second die from the position of at least one of the wafer stage 43 (substrate holding unit) and the bonding head 423 (carrier holding unit) upon bonding the second die to the first die. The positions of these holding units can be obtained from an interferometer configured to measure the position of the bonding head 423 and the interferometer 422 configured to measure the position of the wafer stage 43. Furthermore, it is also possible to obtain (estimate) the positional shift amount between the first die and the second die from the information indicating the presence/absence of an abnormality upon bonding the second die to the first die. The information indicating the presence/absence of an abnormality can be obtained by the control unit 441 monitoring respective units related to bonding of the first die and the second die.

In step S105, the quality information (rank information) indicating the quality of each first die bonded with the second die is obtained. In this embodiment, the quality information is obtained by updating the rank information obtained in step S101, more specifically, the quality (data concerning the quality) of each first die (die 61) so as to be consistent with the bonding result (evaluation result thereof) of the first die and the second die. Note that, instead of updating the rank information, the bonding result of the first die and the second die evaluated in step S104 may be used as the quality information indicating the quality of each first die bonded with the second die. As has been described above, in this embodiment, the dies 51 mounted on the dicing frame 5 are the second dies and the third dies. Hence, the rank information obtained in step S101 includes the quality (data concerning the quality) of each third die. However, there is a case where the second die and the third die are mounted on different dicing frames, so the rank information of the third die, that is, the data concerning the quality of each third die has not been obtained. In this case, together with the quality information indicating the quality of each first die bonded with the second die, for example, the data concerning the quality of each third die is obtained from the external apparatus such as the prober. Alternatively, in step S101, the rank information including the data concerning the quality of each third die may be obtained in addition to the rank information including the data concerning the quality of each second die.

In step S106, based on the quality information obtained in step S105 and the data concerning the quality of each third die, a combination of the first die bonded with the second die and the third die to be bonded to the first die is decided such that non-defective dies are bonded together and defective dies are bonded together. Note that, if a combination of non-defective dies or a combination of defective dies cannot be decided, a combination of the non-defective first die after bonding and the defective third die or a combination of the defective first die after bonding and the non-defective third die is decided.

In step S107, in accordance with the combination decided in step S106, the first die (die 61) bonded with the second die (die 51) and the third die (die 51) are bonded. Note that the bonding order is arbitrary as long as the combination of the first die bonded with the second die and the third die to be bonded thereto matches the combination decided in step S106. If, among the dies mounted on the dicing frame, all the third dies included in the combinations decided in step S106 have been bonded to the first dies, the dicing frame is exchanged. Then, in accordance with the combinations decided in step S106, the third dies are bonded to all the first dies bonded with the second dies.

Here, processing (step S102) of deciding the combination of the first die and the second die and processing (step S106) of deciding the combination of the first die bonded with the second die and the third die will be more specifically described. Note that these processing operations are similar except that, as the data indicating the quality of each first die, the rank information obtained in step S101 is used or the quality information obtained in step S105 is used. Here, let M be the total number of the dicing frames 5 supplied to the bonding apparatus BD. Further, let Cg be the total number of the non-defective dies 61 (first dies) formed on the wafer 6, Cb be the total number of the defective dies 61, Dg be the total number of the non-defective dies 51 (second dies and third dies) mounted on M dicing frames 5, and Db be the total number of the defective dies 51.

First, from the dicing frames 5 supplied to the bonding apparatus BD, the dicing frame that satisfies the condition “Cg≤Dg” and “Cb≤Db” is selected. There can be a case where all the dicing frames 5 supplied to the bonding apparatus BD do not satisfy the condition. In this case, m dicing frames that satisfy the condition “Cg≤the total number of the non-defective dies 51 on m dicing frames” and “Cb≤the total number of the defective dies 51 on m dicing frames” are selected. At this time, the dicing frames are selected to minimize m. Note that arbitrary dicing frames can be selected as long as the condition is satisfied. Then, a combinations of the die 61 (first die) on the wafer and the dies 51 (second die and third die) on the selected m dicing frames to be bonded is decided. Note that the combination of the die 61 and the dies 51 to be bonded is arbitrary as long as it is a combination of non-defective dies or a combination of defective dies. For example, if the rank information shown in FIG. 4 is obtained, by the above-described processing, the dicing frame D12 or D13 is selected, and the combination of the die 61 and the dies 51 to be bonded is decided.

In this manner, according to this embodiment, it is possible to increase the number of bonds of the non-defective die 61 (first object) and the non-defective dies 51 (second object and third object) and the number of bonds of the defective die 61 and the defective die 51. Accordingly, it is possible to suppress a decrease in yield (improve the yield) of a bonded object (device) including the die 61 (first object) and two dies 51 (second object and third object) and obtained by performing bonding a plurality of times.

Note that, in the processing of bonding the second die to the first die and the processing of bonding the third die to the first die bonded with the second die, dies of the same kind may be bonded to the first die as in this embodiment. Therefore, for the dicing frame as the second carrier, the dicing frame as the first carrier not used in the processing of bonding the second die to the first die may be used. On the other hand, a plurality of kinds of dies may be mounted on the dicing frame. In this case, the second die not bonded to the first die, that is, the unbonded second die may be used as the third die if the combination of the first die and the third die matches the combination of a high priority order. Further, the dicing frame (first carrier) mounted with the second die used as the third die may be used in the processing of bonding the second die to the first die.

In this embodiment, it is assumed that the allowable range (threshold value) used in evaluating the bonding result of the first die and the second die is set from the measurement result obtained by actually measuring the intermediate bonded object obtained by actually bonding the first die and the second die, but the present invention is not limited to this. For example, the allowable range used in evaluating the bonding result of the first die and the second die may be set from the intermediate bonded object of the first die and the second die obtained by simulation, that is, from the simulation result. In this case, it is unnecessary to actually bond the first die and the second die to obtain the intermediate bonded object. This is useful for the first bonding of dies. It is also possible to directly evaluate the bonding result of the first die and the second die from the intermediate bonded object (simulation result) of the first die and the second die obtained by simulation.

This embodiment premises that all the dies 61 (first dies) formed on the wafer 6 supplied to the bonding apparatus BD are bonded with the dies 51 (second objects and third objects) mounted on the dicing frame 5. The reason why the die 51 is bonded to the defective die 61 is that, as has been described above, it is necessary to bond (arrange) the die 51 to even the defective die 61 to suppress a deterioration in uniformity in the molding and bonding processes. However, in a case where there is no influence in the molding and bonding processes even if the dies 61 (first dies) vary, it is unnecessary to bond the dies 51 (second die and third die) to the defective die 61. In this case, the combination of the die 61 and the die 51 to be bonded is decided by paying attention only to bonding of non-defective dies. When all the non-defective dies 61 (first dies) on the wafer have been bonded with the dies 51 (second dies and third dies), the bonding operation may end.

### Second Embodiment

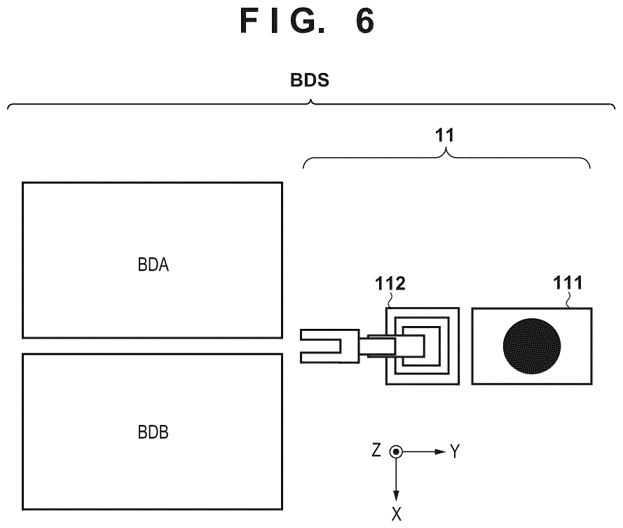

FIG. 6 is a view showing the configuration of a bonding system BDS including a plurality of bonding apparatuses BD. The bonding system BDS includes a first bonding apparatus BDA and a second bonding apparatus BDB as the plurality of bonding apparatuses BD. Each of the first bonding apparatus BDA and the second bonding apparatus BDB has the configuration and function similar to those of the bonding apparatus BD shown in FIG. 1. The bonding system BDS also includes a wafer supply unit 11 as shown in FIG. 6.

The wafer supply unit 11 includes a wafer pod 111 and a wafer conveyance arm 112. The wafer pod 111 is formed to be detachable, and supplied from outside the apparatus while storing (mounted with) a plurality of wafers 6. The wafer conveyance arm 112 takes out the wafer 6 from the wafer pod 111, and conveys (passes) the wafer 6 to a bonding unit 4 of the first bonding apparatus BDA or the second bonding apparatus BDB. Further, the wafer conveyance arm 112 conveys (returns) the wafer 6 completed with a bonding process from the bonding unit 4 of the first bonding apparatus BDA or the second bonding apparatus BDB to the wafer pod 111. Note that, in this embodiment, only one wafer conveyance arm 112 conveys the wafer 6, but a plurality of wafer conveyance arms 112 may relay the wafer 6. In order to increase the cleanliness, after the wafer 6 is loaded to the first bonding apparatus BDA or the second bonding apparatus BDB, the wafer 6 may pass through a mechanism for cleaning the wafer 6 inside the first bonding apparatus BDA or the second bonding apparatus BDB and a mechanism for executing preprocessing for bonding. Furthermore, from the viewpoint of shortening the exchange time of the wafer pod 111 and the conveyance time of the wafer 6, the bonding system BDS may include a plurality of wafer supply units 11.

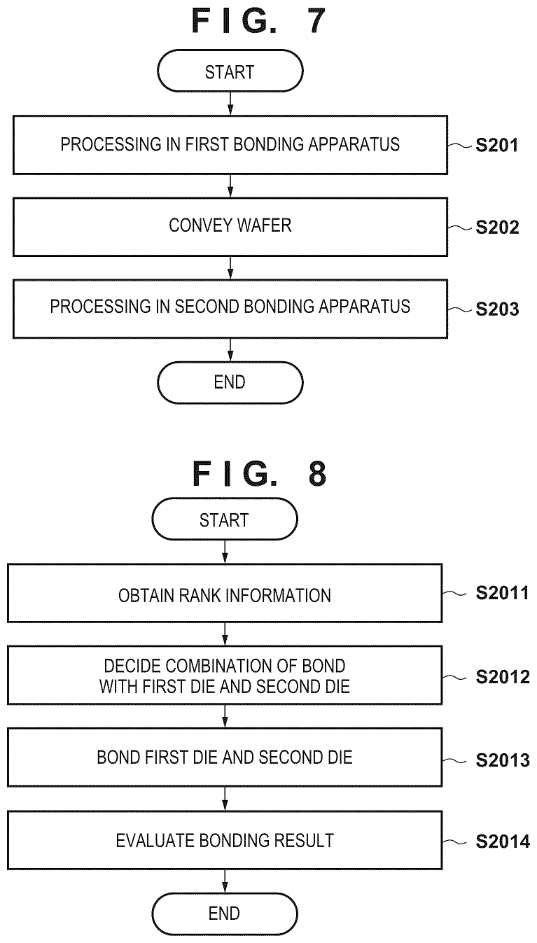

With reference FIG. 7, an operation in the bonding system BDS, that is, a bonding operation (bonding method) of bonding a die 51 (second object) to a die 61 (first object) on the wafer 6 and further bonding the die 51 (third object) to the die 61 bonded with the die 51 will be described. The bonding operation in the bonding system BDS is roughly divided into steps S201, S202, and S203 as shown in FIG. 7. In step S201, a bonding process (a process in the first bonding apparatus BDA) is performed in the first bonding apparatus BDA. In step S202, the wafer 6 having undergone the bonding process in step S201 is conveyed from the first bonding apparatus BDA to the second bonding apparatus BDB by using the wafer conveyance arm 112. Note that, when conveyed from the first bonding apparatus BDA to the second bonding apparatus BDB, the wafer 6 may pass through the wafer pod 111. In step S203, a bonding process (a process in the second bonding apparatus BDB) is performed in the second bonding apparatus BDB.

With reference to FIG. 8, the process (step S201) in the first bonding apparatus BDA shown in FIG. 7 will be more specifically described. In step S2011, rank information concerning the wafer 6 and a plurality of dicing frames 5 stored in a frame magazine 71 supplied (conveyed) to the first bonding apparatus BDA is obtained. In step S2012, based on the rank information obtained in step S2011, the combination of the first die (die 61) and the second die (die 51) to be bonded to the first die is decided such that non-defective dies are bonded together and defective dies are bonded together. In step S2013, in accordance with the combination decided in step S2012, the first die (die 61) and the second die (die 51) are bonded. In step S2014, the bonding result of bonding the second die to the first die in step S2013 (that is, the quality of the first die after the second die is bonded thereto) is evaluated. During conveyance of the wafer 6 from the first bonding apparatus BDA to the second bonding apparatus BDB in step S202, a foreign substance may adhere to the wafer 6. In this case, the quality information of the first die bonded with the second die may be changed. Therefore, evaluating the bonding result of the first die and the second die (step S2014) may be performed as the process in the second bonding apparatus BDB after step S202. Note that processing in steps S2011 to S2014 is similar to that in steps S101 to S104 described in the first embodiment, so that a detailed description is omitted here.

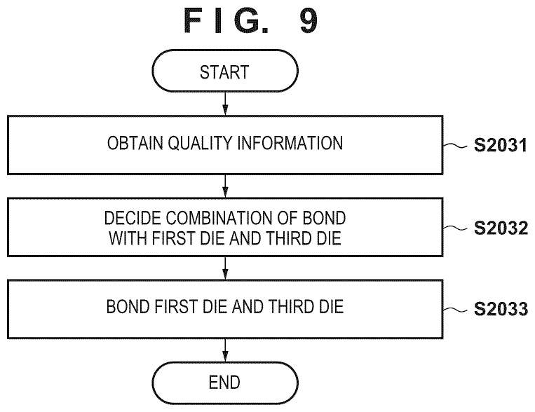

With reference to FIG. 9, the process (step S203) in the second bonding apparatus BDB shown in FIG. 7 will be more specifically described. In step S2031, the quality information (rank information) indicating the quality of each first die bonded with the second die is obtained. In step S2032, based on the quality information obtained in step S2031 and data concerning the quality of each third die, the combination of the first die bonded with the second die and the third die to be bonded thereto is decided such that non-defective dies are bonded together and defective dies are bonded together. In step S2033, in accordance with the combination decided in step S2032, the third die (die 51) is bonded to the first die (die 61) bonded with the second die (die 51). Note that processing in steps S2031 to S2033 is similar to that in steps S105 to S107 described in the first embodiment, so that a detailed description is omitted here.

In this manner, also in this embodiment, it is possible to increase the number of bonds of the non-defective die 61 (first object) and the non-defective dies 51 (second object and third object) and the number of bonds of the defective die 61 and the defective dies 51. Accordingly, it is possible to suppress a decrease in yield (improve the yield) of a bonded object (device) including the die 61 (first object) and two dies 51 (second object and third object) and obtained by performing bonding a plurality of times.

### Third Embodiment

A method of manufacturing an article (a semiconductor IC element, a liquid crystal display element, a MEMS, or the like) using the above-described bonding apparatus BD and bonding system BDS (bonding method (bonding operation)) in the above-described embodiments will be described. The manufacturing method includes a step of preparing a plurality of substrates (wafers 6) on each of which a plurality of first objects (dies 61) have been formed, and a step of preparing the first carrier (dicing frame 5) on which a plurality of separated second objects (dies 51) are mounted. The manufacturing method also includes a step of preparing the second carrier (dicing frame 5) on which a plurality of separated third objects (dies 51) are mounted. The manufacturing method further includes a step of forming a bonded object formed by sequentially bonding the second object and the third object to the first object using the bonding apparatus BD and the bonding system BDS, and a step of manufacturing an article by processing the bonded object in another known process. The other known process includes probing, dicing, bonding, packaging, and the like. The article manufacturing method according to this embodiment is advantageous in at least one of the performance, quality, productivity, and production cost of the article, as compared to conventional methods.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent application No. 2023-140268 filed on Aug. 30, 2023, which is hereby incorporated by reference herein in its entirety.

What is claimed is:

1. A bonding method of bonding a third object after bonding a second object to a first object, the method comprising:
evaluating a bonding result of bonding the second object to the first object;
deciding, based on the bonding result, the third object to be bonded to the first object bonded with the second object from a plurality of the third objects; and
bonding, based on the decision in the deciding, the third object to the first object bonded with the second object.

2. The method according to claim 1, wherein
in the evaluating, as the bonding result, a positional shift amount between the first object and the second object bonded to the first object is evaluated.

3. The method according to claim 2, wherein
in the deciding, based on the positional shift amount and rank information including data indicating a rank of each third object, the third object to be bonded to the first object bonded with the second object is decided.

4. The method according to claim 3, wherein
the rank information includes data concerning a quality of the third object, and
in the decided, the third object to be bonded to the first object bonded with the second object is decided such that the third object as a non-defective object is bonded to the first object having the positional shift amount within an allowable range.

5. The method according to claim 4, wherein
in the decided, the third object to be bonded to the first object bonded with the second object is decided such that the third object as a defective object is bonded to the first object having the positional shift amount outside an allowable range.

6. The method according to claim 2, wherein
in the decided, the third object to be bonded to the first object bonded with the second object is decided based on the positional shift amount and rank information including data indicating a rank of each first object and data indicating a rank of each third object.

7. The method according to claim 6, wherein
in the decided, for the first object having the positional shift amount within an allowable range, the third object to be bonded to the first object bonded with the second object is decided such that the first object and the third object are bonded in descending order of a priority order decided in advance in accordance with a combination of the rank of the first object and the rank of the third object.

8. The method according to claim 7, wherein
the priority order is decided in advance such that a combination in which the rank of the first object and the rank of the second object are more similar has a higher priority order.

9. The method according to claim 8, wherein
the priority order is decided in advance such that a combination in which the rank of the first object and the rank of the second object are the same has a highest priority order.

10. The method according to claim 4, wherein
in the decided, the third object to be bonded to the first object bonded with the second object is decided such that the third object as a defective object is bonded to each of the first object having the positional shift amount outside an allowable range and the first object as a defective object.

11. The method according to claim 4, wherein
in the decided, the third object to be bonded to the first object bonded with the second object is decided such that the third object is not bonded to the first object as a defective object.

12. The method according to claim 2, wherein
in the evaluating, the positional shift amount is obtained from one of an image obtained by capturing the first object bonded with the second object, a load value upon bonding the second object to the first object, a position of at least one of a substrate holding unit holding the substrate and a carrier holding unit holding the first carrier upon bonding the second object to the first object, and information indicating a presence/absence of an abnormality upon bonding the second object to the first object.

13. The method according to claim 1, wherein
processing of bonding the second object to the first object and processing of bonding the third object to the first object bonded with the second object are performed by the same bonding apparatus.

14. The method according to claim 1, wherein
processing of bonding the second object to the first object and processing of bonding the third object to the first object bonded with the second object are performed by different bonding apparatuses.

15. The method according to claim 1, further comprising conveying, to a bonding apparatus, a substrate formed with the first object, a first carrier holding a plurality of the second objects, and a second carrier holding a plurality of the third objects.

16. The method according to claim 15, wherein
the second object and the third object are objects of the same kind, and
the first carrier and the second carrier are the same carrier.

17. The method according to claim 15, wherein
the number of the first objects formed on the wafer is larger than the number of the second objects mounted on the first carrier and the number of the third objects mounted on the second carrier.

18. A bonding apparatus that bonds a third object after bonding a second object to a first object, the apparatus comprising:
an evaluation unit configured to evaluate a bonding result of bonding the second object to the first object;
a decision unit configured to decide, based on the bonding result, the third object to be bonded to the first object bonded with the second object from a plurality of the third objects; and
a bonding unit configured to bond the third object to the first object bonded with the second object based on the decision of the decision unit.

19. An article manufacturing method comprising:
preparing a first object;
preparing a second object;
preparing a third object;
forming a bonded object by bonding the third object after bonding the second object to the first object in accordance with a bonding method defined in claim 1; and
manufacturing an article by processing the bonded object.
